(19) United States
(12) Patent Application Publication
(10) Pub. No.: US 2022/0123194 A1
(43) Pub. Date: Apr. 21, 2022

(54) High Temperature Superconducting Device

(71) Applicants: Carlo A. Trugenberger, Cologny (CH); Valerii M. Vinokour, Chicago, IL (US); Maria Cristina Diamantini, Cologny (CH)

(72) Inventors: Carlo A. Trugenberger, Cologny (CH); Valerii M. Vinokour, Chicago, IL (US); Maria Cristina Diamantini, Cologny (CH)

(21) Appl. No.: 17/170,584

(22) Filed: Feb. 8, 2021

Related U.S. Application Data
(60) Provisional application No. 63/093,164, filed on Oct. 17, 2020.

(51) Int. Cl. H01L 39/12; H01B 12/06

(52) U.S. Cl. CPC H01L 39/128; H01B 12/06

(57) ABSTRACT

A superconducting structure is presented. In some embodiments, the superconducting structure includes a first plane of material; a second plane of material; and a separating medium positioned between the first plane and the second plane, wherein a superconducting critical temperature of the superconducting structure is adjusted by control of one or more parameters.

### RELATED APPLICATION

The present application claims priority to U.S. Provisional Application No. 63/093,164, entitled “Tailoring Materials with Arbitrary High Superconducting Transition Temperature, Including Room Temperatures and Beyond,” filed on Oct. 17, 2020, which is herein incorporated by reference in its entirety.

### TECHNICAL FIELD

Embodiments of the present invention are related superconducting devices.

### DISCUSSION OF RELATED ART

Superconductivity offers an irreplaceable platform for a broad range of technological and industrial applications ranging from power transfer through the electric grid to quantum computing. Superconducting materials promise to solve the problem of energy storage and transporting electric energy with no power dissipation in the grid. Materials that have been shown to exhibit superconductivity, the property of electrical current flow with no resistance, include chemical elements (e.g. mercury or lead), alloys (e.g., niobium-titanium, germanium-niobium, and niobium nitride), ceramics and crystalline cuprates (bismuth strontium calcium copper oxides, yttrium barium copper oxide, and others, or magnesium diboride), superconducting pnictides (e.g., fluorine-doped LaOFeAs), or organics (e.g., fullerenes and carbon nanotubes), van der Waals devices (having two or more two-dimensional layered materials, for example conducting planes like graphene), and interfaces between insulators, that are cooled below a superconducting transition temperature T_{c}. The major obstacle hindering the development of these technologies lies in the low transition temperature T_{c} to the superconducting state in materials that exhibit superconductivity. There are extensive applications for near room temperature high temperature superconductors. These applications include, for example, highly efficient power transmission over superconducting lines, near frictionless rail transportation over superconducting rails, high-speed and low power electronic devices using superconducting metallization and device interconnects, and high temperature operating supercomputer devices with superconducting qubits.

The discovery of high-Tc superconductivity became a major breakthrough that has allowed the start of more technological applications of superconducting materials. Materials have been considered to exhibit high temperature superconductivity if the transition temperature T_{c} below which the material exhibits superconductivity is above 30 Kelvin (−243.15° C.). In the 1980s a class of superconducting materials began to emerge that exhibited superconductivity at a critical temperature T_{c} above that of liquid nitrogen (77K or −196.15° C.), starting with the paper by J. G. Bednorz and K. A. Muller, “Possible high Tc superconductivity in the Ba—La—Cu—O system,” Z. Phys. B. 64 (1), 189-193 (1986). Materials that have been shown to exhibit high-temperature superconductivity include Hg₁₂T₁₃Ba₃₀Ca₃₀Cu₄₅O₁₂₇ (T_{c}=138K), Bi₂Sr₂Ca₂Cu₃O₁₀ (BSCCO, T_{c}=110K), and YBa₂Cu₃O₇ (YBCO, T_{c}=92K). Each of these superconducting materials exhibit superconductivity at critical temperatures above that of liquid nitrogen. However, the existing limit on critical temperatures T_{c} of about 100 K is not sufficient for broad technological and commercial applications since the related costs for refrigeration remain high.

Some materials have been shown to exhibit superconductivity at higher transition temperatures under pressure, for example hydrogen sulfide (T_{c}=203K at 100 GPa) and LaH₁₀ (T_{c} at 250 K at 170 GPa). In October of 2020, a group from the University of Rochester announced a material that exhibits superconductivity at near room temperature. (Elliot Snider, Nathan Dasenbrock-Gammon, Raymond McBride, Mathew Debessai, Hiranya Vindana, Kevin Vencatasamy, Keith V. Lawler, Ashkan Salamat, and P. Ranga, “Room-temperature superconductivity in a carbonaceous sulfur hydride,” Nature 586 (7329), 373-377 (October 2020). In particular, a compound of photosynthesized carbonaceous sulfer hybride (H₂S+CH₄) exhibited superconductivity at Tc=287K (14° C.) at a pressure of 267 GPa.

Therefore, there is a need to develop better superconducting devices that operate at temperatures near room temperature. Such devices do not need cooling with cryogenic materials and may only need chilled water cooling to function.

### SUMMARY

In some embodiments, a superconducting structure is presented. In some embodiments, the superconducting structure includes a first plane of material; a second plane of material; and a separating medium positioned between the first plane and the second plane, wherein a superconducting critical temperature of the superconducting structure is adjusted by control of one or more parameters.

A method of forming a superconducting structure according to some embodiments includes determining a material for a first plane and a second plane; determining a separating medium; determining a separation between the first plane and the second plane based on a Bohr radius of the material; assembling the superconducting structure with the separating medium positioned between the first plane and the second plane; and adjusting one or more operating parameters to adjust a superconducting critical temperature of the superconducting structure.

These and other embodiments are discussed below with respect to the following figures.

### BRIEF DESCRIPTION OF THE FIGURES

FIG. 1 illustrates a device according to some embodiments.

FIG. 2A illustrates a structure of an iron-based superconductor with Se/As planes.

FIG. 2B illustrates a unit cell of Bi₂Sr₂Ca₂Cu₃O₁₀ (BSCCO).

FIGS. 3A and 3B illustrates a electron pairing from magnetic monopole production.

FIG. 4 illustrates a high-temperature superconducting device according to some embodiments.

FIG. 5 illustrates a process for constructing a high-temperature superconducting device according to some embodiments.

These and other aspects of embodiments of the present invention are further discussed below.

### DETAILED DESCRIPTION

In the following description, specific details are set forth describing some embodiments of the present invention. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure.

This description illustrates inventive aspects and embodiments should not be taken as limiting—the claims define the protected invention. Various changes may be made without departing from the spirit and scope of this description and the claims. In some instances, well-known structures and techniques have not been shown or described in detail in order not to obscure the invention.

Throughout the specification, reference is made to theoretical explanations for the behaviors expected in the various embodiments presented. These descriptions and explanations are intended to assist in understanding the behavior of the embodiments disclosed below. The explanations provided below are not intended to be limiting of the claimed invention in any way. The claimed invention is not limited by any of the scientific theories used to help explain the behavior of specific devices described below.

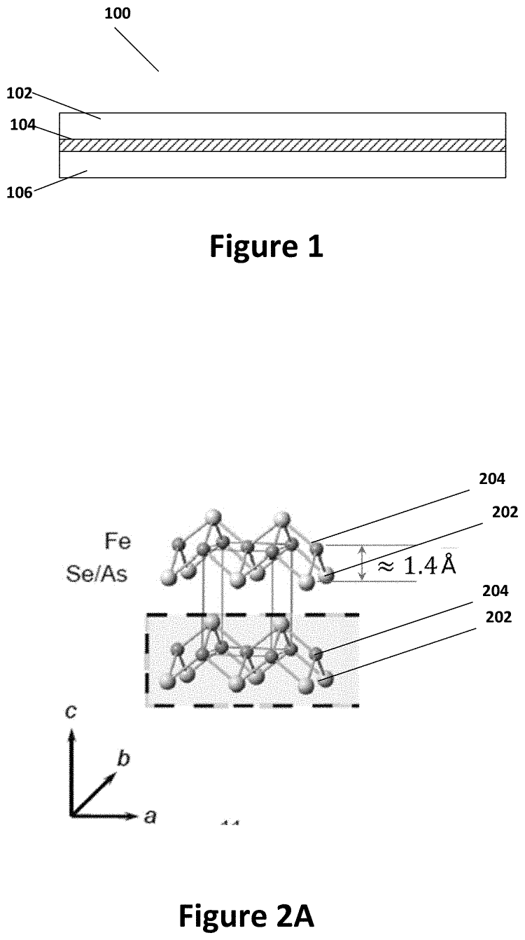

FIG. 1 illustrates a superconducting device 100 according to some embodiments of the present disclosure. As illustrated in FIG. 1, an arbitrarily high superconducting transition temperature T_{c}, going to room temperature and beyond, can be realized by two conducting or superconducting planes, plane 102 and plane 106. Plane 102 and plane 106 can be, for example, CuO planes in cuprates, Fe planes in iron-based superconductor families, C planes in graphite-type materials, or other suitable materials. The conducting planes 102 and 106 are separated by separation medium 104. Separation medium 104 can be, for example, one or more atomic planes (e.g., cuprates, pnictides, or other materials); insulating material layers (for example as in vdW-like devices); an empty space of the atomic scale (for example in the atomic structure of superconducting material used for planes 102 and 106 where monopole density can be controlled); or other medium. If the separation medium 104 is one or more atomic planes, then the atomic structure can include sulfur layers or other suitable atoms, especially if conducting planes 102 and 106 are graphite-like carbon plates. For example, separation medium 104 can be formed of Ca in BSCCO, Se/As atomic planes in iron-based superconductors, an oxide, or some other insulating planes as in van der Waals devices.

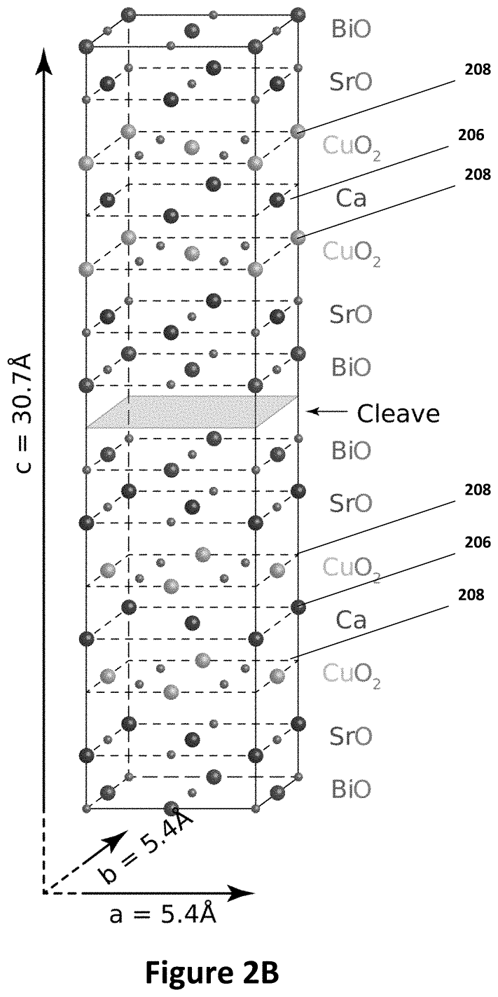

FIG. 2A illustrates the Se/As atomic planes 202 in an iron-based superconductor. FIG. 2B illustrates a unit cell of BSCCO, which illustrates the Ca planes 206. As is illustrated in FIGS. 2A and 2B, the structure illustrated in FIG. 1 can be stacked. The conducting planes 102 and 106 (the Fe planes 204 in FIG. 2A and the CuO2 planes 208 in FIG. 2B) are separated by the Se/As plane 202 in FIG. 2A or the Ca plane 206 in FIG. 2B. Other materials systems may have other structures and FIGS. 2A and 2B are illustrated as examples only.

Returning to FIG. 1, the separation between plane 102 and plane 106 is about atomic thickness empty separation or to accommodate one or a few more insulating atomic planes in separation medium 104. The thickness of separation medium 104, then, can be about one or a few Angstrom, and a few Angstrom thick in van der Waals (vdW) devices. In some embodiments, for example vdW devices separation medium 104, can be an empty space between, planes 102 and 106 that can each be formed of graphene, nitride or some other conducting materials, or by layering a conducting plane 106 with an insulating plane for separation medium 104 and then conducting plane 102, forming a structure with separation medium 104 formed in between conducting planes 102 and 106. Separation medium 104 can be formed of a thin (one or a few atoms in thickness) insulating material. Such a structure can theoretically realize an arbitrarily high superconducting transition temperature going to room temperatures (e.g., 20° C.) and beyond. As illustrated in FIG. 1, the material system 100 exhibiting an elevated superconducting transition temperature includes two conducting planes (planes 102 and 106) separated by either a free space or one or a few rows of other atoms in between to form the separating medium 104.

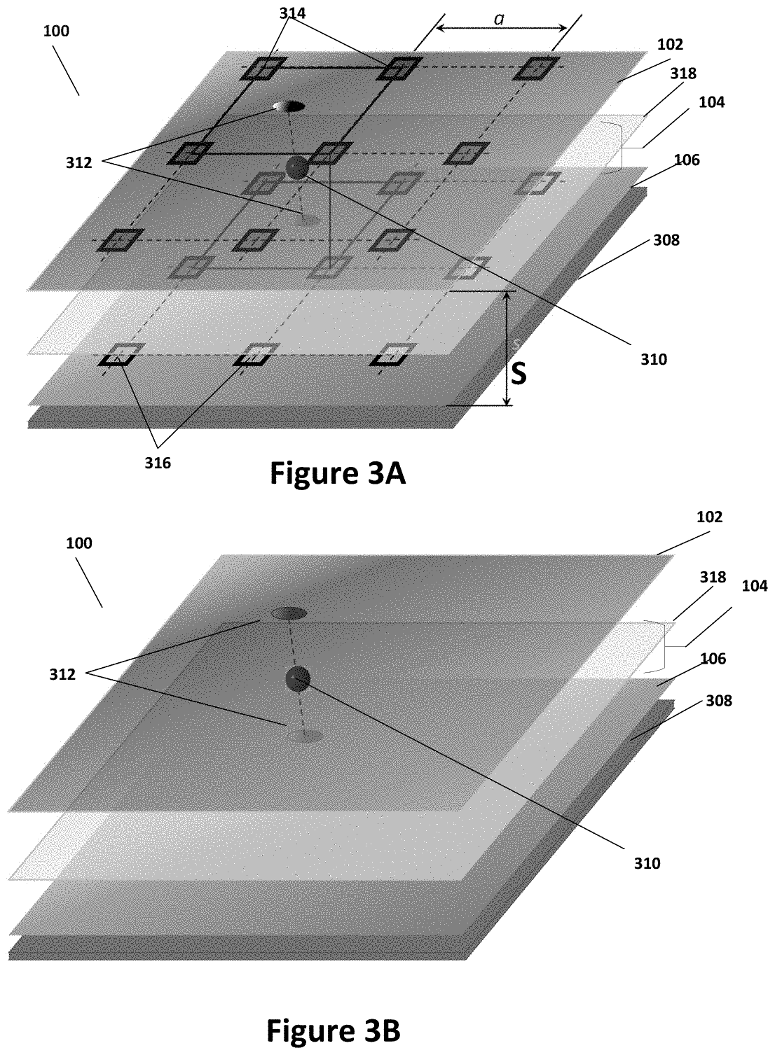

While charge conduction is restricted mostly to within planes 102 and 106, the electron pairing and the formation of a bosonic doublet that Bose condenses and leads to superconductivity is a three-dimensional inter-plane effect and can be associated with the emergence of magnetic monopoles. Contrary to the usual Bardeen-Cooper-Schrieffer mechanism of pairing via phonon-mediated electron-electron attraction to form Cooper pairs, in high-T_{c} materials pairing of Cooper pairs is induced by other mechanism, among which is the presence of magnetic monopoles emerging in separating medium 104 between planes 102 and 106. This mechanism is illustrated in FIGS. 3A and 3B. The origin of monopoles is discussed in greater detail in M. Cristina Diamantini, C. A. Trugenberger and Valerii M. Vinokur, “Confinement and asymptotic freedom with Cooper pairs”, Nature Comm. Phys. 2018, 1:77, 10.138.

FIGS. 3A and 3B further illustrate electron pairing in device 100. As illustrated device 100 includes planes 102 and 106 separated by separation medium 104. Planes 102 and 106 can be conducting planes that are near a superconducting-insulating transition (SIT) condition. FIG. 3A further illustrates positions of atoms 314 and 316 within the planes 102 and 106. For example, atoms 314 are illustrated in plane 102 and atoms 316 are illustrated in plane 106. Atoms are separated by distances, e.g., a as illustrated in FIG. 3A. FIG. 3B is presented without the atom positions for better illustration.

As illustrated in FIGS. 3A and 3B, separation medium 104 can include a plane 318. As shown in FIG. 3A, a gate 308 (which can be a coil inducing the magnetic field) can be included to provide an electrical or magnetic field across planes 102 and 106. As is further illustrated in FIG. 3A, a magnetic monopole 310 can be produced within separation medium 104 under the conditions that are further discussed below.

Magnetic monopole 310 is illustrated as emerging between conducting planes 102 and 106 and forms a potential well for two electrons localized within the opposite conducting planes, illustrated as electron pairs 312 in FIGS. 3A and 3B. The fact that electrons move mostly within planes whereas the tunneling between planes is a rare event, results in the trend of the formed electron pairs 312 to have higher orbital (e.g., to form d-orbital) moments.

FIG. 3A reflects a discrete structure of conducting planes 102 and 106. A square regular array is taken in illustrative purposes; the real atomic structure of the planes is arbitrary without the loss of generality. As illustrated in FIGS. 3A and 3B, in operation, a magnetic monopole 310 can be formed in a volume formed in a 3D parallelepiped in device 100. As illustrated above in FIGS. 2A and 2B, materials structures can be described by atomic separations c (in the Z direction) and (a, b) in the x-y plane. In FIG. 3A, the separation a in the x-y plane is provided, although the atomic separation in some materials can be characterized as both distances a and b in the x-y plane. The 3D parallelepiped in device 100 can be formed by length s in the c-direction and lengths na depicting the x-y spacing of atoms 314 and 316. In this case, a can be the size of the atomic elemental cell on planes 102 and 106, and n being an integer of order 1. The length na, in effect, defines the spatial scale ξ of the resulting superconducting electron pair 312.

As illustrated in FIGS. 3A and 3B, atomic plane 318 in separation medium 104 can be an insulating material that is positioned between conducting layers 102 and 106 or an empty space separation. Plane 318 may also serve as a reservoir of electrons regulating the effective electron density, thus promoting creation of monopoles 310. The magnetic monopoles 310 create a short distance attractive spatial domain of the potential, or the potential well, in which electrons form a bosonic bound state, the electron-electron repulsion is overcome, and Cooper pairs (electron pairs 312) are formed. These bosonic bound states have all the characteristics of a high angular momentum state as illustrated in FIGS. 3A and 3B. The strength of the binding potential increases with the decreasing separation s between charge carrying planes 102 and 106, enabling elevation of the superconducting transition temperature of device 100. Since the only energy scale involved in system 300 is the Fermi energy (the difference between the highest and lowest occupied single-particle states in separation medium 104), the superconducting transition temperature T_{c} can be as high as 1000 Kelvin.

Device 100, as illustrated in FIG. 1 and FIGS. 3A and 3B, comprises two parallel conducting planes 102 and 106 that sandwich an insulating material plane 318. By controlling one or more parameters influencing the electronic parameters of planes 102 and 106 as well as the composition of the insulating plane 318, a superconductor-insulator transition (SIT) at low temperatures at a quantum critical point (QCP) can be realized. The SIT refers to a quantum phase transition where electrons in the superconducting material planes 102 and 106 acquire a granular structure promoting creation of monopoles 310. The QCP can be achieved by adjusting parameters p (e.g., doping, pressure, application of electric or magnetic fields, or other structural parameters). These parameters p can refer, for example, to doping of the materials in superconducting planes 102 and 106 in device 100, application of pressure to device 100, or application of electric or magnetic fields to superconducting device 100. Consequently, upon varying one or more tuning parameters p around its critical value p_{c}, a phase change to superconductivity can be realized.

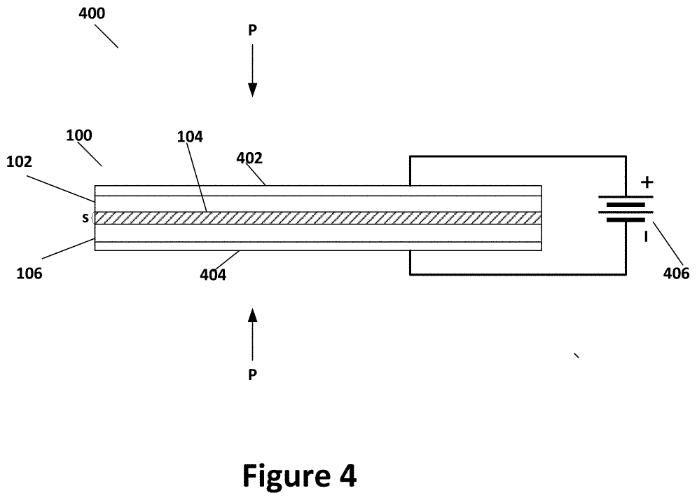

FIG. 4 illustrates further aspects of embodiments of a high-temperature superconducting (HTS) device 400 according to some embodiments of this disclosure. As illustrated in FIG. 4, in some embodiments additional layers can be sandwiched with conducting planes and gates. These additional layers can serve as additional reservoirs of electrons. The voltage applied to the gates, which can be included in these additional layers, may also serve to enhance or deplete the electron density. As illustrated in FIG. 4, and discussed above, plane 102 is a conducting plane and is depicted in FIG. 4 as adjacent to a layer 402. Layer 402 includes a conductive plane and may further include other conductive and insulating planes. Similarly, as discussed above plane 106 is a conducting plane and is depicted in FIG. 4 as adjacent to layer 404. Layer 404 includes a conductive plane and may include other conductive or insulating planes. As is further illustrated in FIG. 4 and discussed above with respect to FIGS. 3A and 3B, planes 102 and 106 are separated by a separation distance s.

As illustrated in the example illustrated in FIG. 4, layers 102 and 106 are adjacent to layers 402 and 404 that include conductive planes that are coupled to a power source 406. Consequently, layers 402 and 404 operate as gates and can be charged to provide electric fields across planes 102, 106, and separation medium 104. In some embodiments, layers 402 and 404 can include magnetic coils driven by power source 406 to provide magnetic fields that can also work as a tuning parameter that takes device 100 close to the quantum point associated with the SIT, which promotes the self-induced electronic granularity and regulating the number of monopoles as was discussed above.

Device 400 can be formed into a long superconducting wire. Alternatively, device 400 may be patterned to form, for example, a Josephson junction array or other such structure.

The separation s between two base conducting planes 102 and 106 is of the atomic scale and therefore allows for quantum tunneling between the planes 102 and 106. In the vicinity where the tuning parameters p are near p_{c}, planes 102 and 106 acquire the self-induced electronic granularity with the characteristic spatial scale of the texture of order ξ and generate magnetic monopoles as discussed above. Magnetic monopoles serve as nucleation centers of spatially localized Cooper pairs such as electron pairs 312 illustrates in FIGS. 3A and 3B formed by two electrons with opposite spins bound by the attractive field of the monopole 310. Upon cooling, the wave functions of localized Cooper pairs 312 increasingly overlap and at the superconducting transition temperature T_{c} form globally coherent Cooper pair condensate, also the size of the Cooper pairs may remain less than the distance between the center of mass of the Cooper pairs and the overlap is achieved via the exponential or other tails of the wave functions. Since the presence of other monopoles improve electron binding, increasing the density of monopole plasma raises T_{c}. Thus, tailoring artificial high-temperature superconducting (HTS) devices 100 with high at-will T_{c} implies operating with a monopole density that is controlled by parameters s and/or p.

Consequently, to provide for HTS device 400 as illustrated in FIG. 4, the composition of possible materials for planes 102 and 106, separation medium 104, the separation s between layers 102 and 106, as well as the electric or magnetic fields produced by layers 402 and 404 and power supply 406 are adjusted. The separation s and the composition of separation medium 104 are parameters that can be set on assembly of HTS device 400 while the electric and/or magnetic fields applied across separation medium 104 can be produced during operation of HTS device 400. Further, in some embodiments, the parameter p can include pressure that can be applied through construction of device 400 or may be applied externally during operation of device 400 by housing device 400 in a pressure vessel or clamping device 100 between layers 402 and 404.

The energy for splitting the Cooper pair 312 and destroying superconductivity in planes 102 and 106 first increases with decreasing distance s between layers 102 and 106, but then can drop passing some maximum. Consequently, the superconducting transition temperature T_{c} first increases as the distance s between the planes of layers 102 and 106 is decreased, but then drops upon passing the maximum. Consequently, aspects of the present disclosure are directed to increasing the superconducting transition temperature T_{c} to near room temperature (e.g., above 0° C.) and above, which can be achieved by the design of or manufacture of materials where the distance between the planes can be tuned by chemical or mechanical methods such that the separation s between layers 102 and 106 being atomically small, decreases further. Additionally, in some embodiments high electric or magnetic fields can be applied. The composition of separation medium 104 can be contained between sufficiently close conducting planes 102 and 106 and possess the monopole-induced potential binding electrons with sufficiently deep energy levels to induce transition to a superconducting state in device 100. Additionally, as discussed above, apart from applying electric and/or magnetic fields, the transition temperature T_{c} may be increased by applying a sufficient pressure to further reduce separation of planes 102 and 106. The addition of pressure can, in some embodiments, promote generation of a sufficient number of monopoles 310 with a deep enough potential well that the transition temperature increases to close to or above room temperature.

In some embodiments according to this disclosure, the candidate materials that can form device 100, a separation medium 104 sandwiched between conducting plans 102 and 106, have a separation between planes 102 and 106 that satisfies the relation

$$\frac{s}{{a}_{B}} < 1 ,$$

where a_{B} is the material Bohr radius of the atoms 314 and 316 in layers 102 and 106. The Bohr radius a_{B} refers to a distance between the nucleus and electron in a particular material and is in the expected range 0.5-5 nm, depending on composition of the material in which planes 102 and 106 are formed. Consequently, the separation between conducting planes 102 and 106 may be less than above 5 nm and may be between 0.05-0.5 nm. In some embodiments, planes 102 and 106 may be carbon planes in graphite or similar material with the base interplane distance of 0.335 nm or similar and the separation medium 104 may be synthesized with intercalation of sulfur or hydrogen atoms to form carbonaceous sulfur-hybride (C—S—C) or hydrogen hybrid (C—H—C) or similar systems where the chemically tuned interplane distance can go down to 0.03 nm. The production of photochemically synthesized C—S—H systems is described, for example, in Elliot Snider, Nathan Dasenbrock-Gammon, Raymond McBride, Mathew Debessai, Hiranya Vindana, Kevin Vencatasamy, Keith V. Lawler, Ashkan Salamat, and P. Ranga, “Room-temperature superconductivity in a carbonaceous sulfur hydride,” Nature 586 (7329), 373-377 (October 2020).

In some embodiments, layers 102 and 106 can be formed of compounds that include conducting layers like cuprates (CuO layers), pnictides (Fe layers), graphite (densely packed carbon layers), vdW graphene-based systems, or vdW transition metals nitrides-based systems, or cuprate-based systems, or vdW comprising other compounds of the kind. Varying a doping parameter p of planes 102 and 106, which may influence s as is in the case of pnictides, or by intercalating interlayer electron or hole donors (in case of graphite) or using an electric gate that changes electron/hole density, the magnetic monopole density can be optimized to achieve the maximal T_{c}. As shown in FIG. 4, the electric gates in layers 402 and 404 can be powered by power source 406 to apply charge on planes 102 and 106.

In some embodiments, artificially prepared atomically thin conducting films that are in the vicinity of the SIT can be used. The candidate atoms or compounds for separation medium 104 include but are not restricted to oxides of the metals constituting conducting planes 102 and 106 Materials that can be used in planes 102 and 106 can include nitrides of the transition metals, graphene monolayers, hybrids composed of two-layered topological insulators, and exfoliated monolayer films of cuprates or pnictides to form a van der Walls (vdW) like devices. The films out of the described materials are collapsed on top of each other to make a double- or electron-reservoir sandwich-like triple layers or like vdW devices. The layer separation s is controlled by the conditions of preparation of the vdW and/or by pressure either mechanically applied to the device or caused by the electric gate that may be the part of the device. Depending on the candidate materials the usual measures preventing contamination or degrading the films are taken.

The HTS device 100 as discussed above can be achieved as illustrated in FIG. 4 with layers 402 and 404 including being sulfur atoms or similar decorated on the surface of a two-layer graphite device in which case planes 102 and 106 can be monoatomic carbon planes or similar monolayer films described above. The decoration serves to increase the electron density thereby promoting the generation of monopoles. In some embodiments, layers 402 and 404 can be iron-cast plates while planes 102 and 106 are formed of graphite. Separation medium 104 between conducting planes 102 and 106 can include intercalating heavy atoms such as, for example, Uranium or Plutonium. Other heavy atoms can be utilized as well.

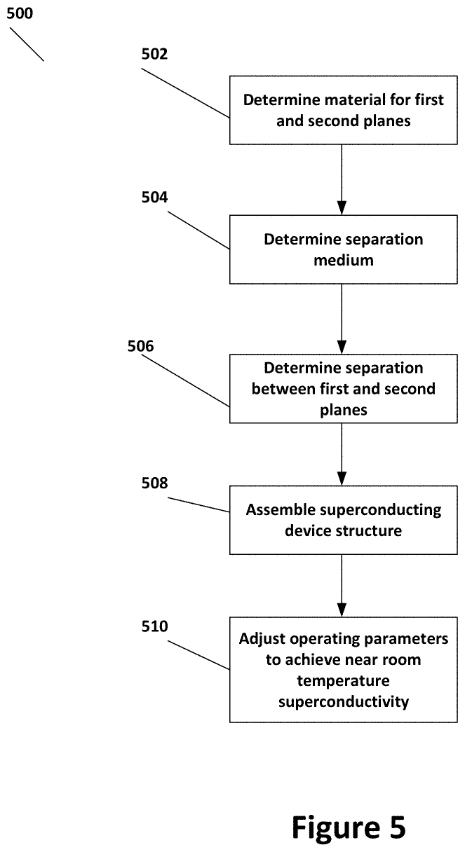

FIG. 5 illustrates a process 500 of providing a superconducting device 100 according to some embodiments of the present disclosure. In step 502, the materials that form a first plane 102 and a second plane 106 are determined. As discussed above, these materials may be conductive or superconducting materials such as, for example, graphite, cuprates, pnictides, or other conducting and superconducting materials as have been previously discussed. In step 504 the separation medium 104 is determined. Determining the materials for planes 102 and 106 and separation medium 104 in steps 502 and 504 may include doping as well, as discussed above. In step 506, the separation s between planes 102 and 106 are determined as described above. In step 508, device 100 can be assembled with planes 102 and 106 and separation medium 104 into superconducting device 100 such as that shown in FIGS. 1 and 4, for example. As discussed above, superconducting device 100 may be assembled to form wires or patterned to form superconducting structures. In step 510, electric or magnetic fields as well as pressure or other operating parameters can be applied to device 100 and adjusted to provide for a superconducting structure 400 where device 100 with a particular superconducting transition temperature T_{c} is formed.

The above detailed description is provided to illustrate specific embodiments of the present invention and is not intended to be limiting. Numerous variations and modifications within the scope of the present invention are possible. The present invention is set forth in the following claims.

What is claimed is:

1. A superconducting structure, comprising:
a first plane of material;
a second plane of material; and
a separating medium positioned between the first plane and the second plane,
wherein the first plane and the second plane are separated by a separation distance, and
wherein a superconducting critical temperature of the superconducting structure is adjusted by control of one or more parameters.

2. The structure of claim 1, wherein the first plane and the second plane include insulating materials.

3. The structure of claim 1, wherein the first plane and the second plane include conducting materials.

4. The structure of claim 1, wherein the separation distance between the first plane and the second plane is less than 5 nm.

5. The structure of claim 4, wherein the separation distance between the first plane and the second plane is less than 0.5 nm.

6. The structure of claim 1, wherein the separation between the first plane and the second plane is less than a Bohr radius of the material of the first plane and the second plane.

7. The structure of claim 3, wherein the conducting material is carbonaceous sulfur hybride.

8. The structure of claim 3, wherein the material of the first plane and the second plane is graphite.

9. The structure of claim 8, wherein the graphite planes of the first plane and the second plane are positioned between iron-cast plates.

10. The structure of claim 9, wherein the separation medium is doped with heavy atoms.

11. The structure of claim 10, wherein the heavy atoms are Uranium or Plutonium.

12. The structure of claim 1, wherein the first plane and the second plane can be formed of graphite, carbon atoms, cuprates, nitrides of transition metals, pnictides, or other conducting materials.

13. The structure of claim 1, wherein the separation medium is one of free space, an insulating material, or one or more atomic planes.

14. The structure of claim 1, further including a power source coupled to layers adjacent to the first plane and the second plane to provide an electric field across the superconducting structure.

15. The structure of claim 1, further including a power source coupled to layers adjacent to the first plane and the second plane to provide a magnetic field across the superconducting structure.

16. The structure of claim 1, further including a pressure system applying pressure to the superconducting structure.

17. The structure of claim 1, wherein the superconducting structure forms a wire.

18. The structure of claim 1, wherein the superconducting structure is patterned.

19. The structure of claim 1, wherein the superconducting structure is achieved by decoration of the first and the second planes

20. A method of forming a superconducting structure, comprising
determining a material for a first plane and a second plane;
determining a separating medium;
determining a separation between the first plane and the second plane based on a Bohr radius of the material;
assembling the superconducting structure with the separating medium positioned between the first plane and the second plane; and
adjusting one or more operating parameters to achieve a superconducting critical temperature of the superconducting structure.

21. The method of claim 20, wherein determining the material for the first plane and the second plane includes determining insulating materials.

22. The method of claim 20, wherein determining the material for the first plane and the second plane includes determining conducting materials.

23. The method of claim 20, wherein determining the separation includes determining that the separation between the first plane and the second plane is less than 5 nm.

24. The method of claim 23, wherein determining the separation includes determining that the separation distance between the first plane and the second plane is less than 0.5 nm.

25. The method of claim 20, wherein determining the separation includes determining that the separation between the first plane and the second plane is less than a Bohr radius of the material of the first plane and the second plane.

26. The method of claim 20, wherein determining the separation material includes determining that the separation material is carbenacous sulfur hybride.

27. The method of claim 26, wherein the material of the first plane and the second plane is graphite.

28. The method of claim 20, wherein the separation medium is free space, an insulating material, or one or more atomic planes.

29. The method of claim 20, wherein the first plane and the second plane can be formed of graphite, cuprates, or pnictides.

30. The method of claim 20, further including providing power to layers adjacent to the first plane and the second plane to provide an electric field across the superconducting structure.

31. The method of claim 20, further including providing power to layers adjacent to the first plane and the second plane to provide a magnetic field across the superconducting structure.

32. The method of claim 20, further including applying pressure to the superconducting structure.

33. The method of claim 20, wherein the superconducting structure forms a wire.

34. The method of claim 20, wherein the superconducting structure is patterned.

35. The method of claim 20, further including decorating the first and the second planes

36. The method of claim 20, wherein the first plane and the second plane are each graphite further including iron-cast plates positioned such that two-layer graphite is positioned between the iron-cast plates, and further including intercalating heavy atoms into the separation medium between conducting planes.

37. The method of claim 36, wherein the heavy atoms are Uranium or Plutonium.
